(19) United States
(12) Patent Application Publication
(10) Pub. No.: US 2025/0253121 A1
(43) Pub. Date: Aug. 7, 2025

(54) SYSTEMS AND METHODS OF SEM INSPECTION USING SELECTIVE SCAN APPROACH

(71) Applicant: KLA Corporation, Milpitas, CA (US)

(72) Inventors: Balaji Srinivasan, Chennai (IN); Weijie Huang, Fremont, CA (US); Harsh Sinha, San Jose, CA (US)

(21) Appl. No.: 18/738,393

(22) Filed: Jun. 10, 2024

(30) Foreign Application Priority Data
Feb. 7, 2024 (IN) 202441008213

(51) Int. Cl. H01J 37/22; G06T 7/11; G06T 7/70; H01J 37/147; H01J 37/28

(52) U.S. Cl. CPC H01J 37/222; G06T 7/11; G06T 7/70; H01J 37/1471; H01J 37/28; G06T 2207/10061; G06T 2207/20084

(57) ABSTRACT

The system includes an electron source configured to generate an electron beam, a stage configured to hold a workpiece in the path of the electron beam, a beam deflector disposed in the path of the electron beam between the electron source and the stage, a detector configured to receive electrons formed when the electron beam impacts the workpiece on the stage, and a processor. The processor is configured to generate a workpiece image based on the electrons received by the detector, determine a size and location of each region of interest (ROI) of the workpiece, determine groups of ROIs having similar size, and send instructions to the beam deflector to direct the electron beam onto the location of each ROI and generate an ROI image for each group of ROIs.

### CROSS-REFERENCE TO RELATED APPLICATIONS

This application claims priority to the provisional patent application filed Feb. 7, 2024, and assigned IN application No. 202441008213, the disclosure of which is hereby incorporated by reference.

### FIELD OF THE DISCLOSURE

This disclosure relates to inspection processes and, more particularly, to semiconductor inspection using a scanning electron microscope.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a workpiece, such as a semiconductor wafer, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

For more than 60% of wafer layers that are subjected to scanning electron microscope (SEM) inspection, less than 50% of the field of view contains a region of interest (ROI). To improve throughput, systems may first perform a low-resolution segmentation scan to identify the ROIs, and then perform a high-resolution detection scan on the regions of interest. However, as ROI count increases and ROI size decreases, the throughput advantages are reduced based on image set up and deflection time to scan the ROI areas. Instead, the high-resolution detection scan is performed on an area much larger than the ROI, which results in scanning unnecessary pixels.

Therefore, what is needed is a selective scanning approach that reduces overhead time and improves throughput.

### BRIEF SUMMARY OF THE DISCLOSURE

An embodiment of the present disclosure provides a system. The system may comprise an electron source configured to generate an electron beam, a stage configured to hold a workpiece in a path of the electron beam, a beam deflector disposed in the path of the electron beam between the electron source and the stage, a detector configured to receive electrons formed when the electron beam impacts the workpiece on the stage, and a processor. The processor may be configured to: generate a workpiece image based on the electrons received by the detector as the electron beam is scanned across the workpiece; determine a size and location of each region of interest (ROI) of the workpiece based on the workpiece image; determine groups of ROIs having similar size based on the size of each ROI of the workpiece, wherein the groups of ROIs comprise a first ROI group and a second ROI group, each comprising a plurality of ROIs; send instructions to the beam deflector to direct the electron beam onto the location of each ROI of the first ROI group; generate a first ROI image based on the electrons received by the detector as the electron beam is scanned across each ROI of the first ROI group; send instructions to the beam deflector to direct the electron beam onto the location of each ROI of the second ROI group; and generate a second ROI image based on the electrons received by the detector as the electron beam is scanned across each ROI of the second ROI group.

In some embodiments, the system may further comprise a memory in electronic communication with the processor, and a deep learning segmentation algorithm may be stored on the memory. The processor may be configured to determine the size and location of each ROI of the workpiece and determine the groups of ROIs based on the deep learning segmentation algorithm.

In some embodiments, the system may further comprise a memory in electronic communication with the processor, and at least one design image may be stored on the memory. The processor may be configured to determine the size and location of each ROI of the workpiece and determine the groups of ROIs based on the at least one design image.

In some embodiments, the beam deflector may comprise an upper main field deflector, an upper sub field deflector, a lower main field deflector, and a lower sub field deflector. The beam deflector may be configured to direct the electron beam onto the location of each ROI by adjusting a voltage applied to the upper sub field deflector and the lower sub field deflector, while a current applied to the upper main field deflector and the lower main field deflector remains constant.

In some embodiments, the workpiece may be divided into a plurality of workpiece sites. The processor may be configured to generate a plurality of workpiece images based on the electrons received by the detector as the electron beam is scanned across each of the plurality of workpiece sites.

In some embodiments, the processor may be configured to determine the size and location of each ROI of the workpiece and determine the groups of ROIs having similar size in parallel with generating the plurality of workpiece images corresponding to each of the plurality of workpiece sites.

In some embodiments, the processor may be further configured to perform a first image setup process for the first ROI group and perform a second image setup process for the second ROI group. The first image setup process may comprise transmitting a first scanning pattern to the beam deflector based on the size of each ROI of the first ROI group, and the second image setup process may comprise transmitting a second scanning pattern to the beam deflector based on the size of each ROI of the second ROI group.

Another embodiment of the present disclosure provides a method. The method may comprise: emitting, with an electron source, an electron beam onto a workpiece, wherein the workpiece is disposed on a stage; receiving, with a detector, electrons formed when the electron beam impacts the workpiece on the stage; generating, with a processor, a workpiece image based on the electrons received by the detector as the electron beam is scanned across the workpiece; determining, with the processor, a size and location of each region of interest (ROI) of the workpiece based on the workpiece image; determining, with the processor, groups of ROIs having similar size based on the size of each ROI of the workpiece, wherein the groups of ROIs comprise at first ROI group and a second ROI group, each comprising a plurality of ROIs; directing, with a beam deflector, the electron beam onto the location of each ROI of the first ROI group; generating, with the processor, a first ROI image based on the electrons received by the detector as the electron beam is scanned across each ROI of the first ROI group; directing, with the beam deflector, the electron beam onto the location of each ROI of the second ROI group; and generating, with the processor, a second ROI image based on the electrons received by the detector as the electron beam is scanned across each ROI of the second ROI group.

In some embodiments, determining, with the processor, the size and location of each ROI of the workpiece based on the workpiece image may comprise determining the size and location of each ROI of the workpiece based on a deep learning segmentation algorithm applied to the workpiece image or based on at least one design image compared to the workpiece image.

In some embodiments, determining, with the processor, the groups of ROIs having similar size based on the size of each ROI of the workpiece may comprise: determining the groups of ROIs having similar size based on the size of each ROI of the workpiece and the deep learning segmentation algorithm or the at least one design image.

In some embodiments, directing, with the beam deflector, the electron beam onto the location of each ROI of the first ROI group may comprise adjusting a voltage applied to an upper sub field deflector and a lower sub field deflector of the beam deflector to direct the electron beam onto the location of each ROI of the first ROI group, while a current applied to an upper main field deflector and a lower main field deflector remains constant.

In some embodiments, directing, with the beam deflector, the electron beam onto the location of each ROI of the second ROI group may comprise adjusting the voltage applied to the upper sub field deflector and the lower sub field deflector of the beam deflector to direct the electron beam onto the location of each ROI of the second ROI group, while a current applied to the upper main field deflector and the lower main field deflector remains constant.

In some embodiments, the workpiece may be divided into a plurality of workpiece sites, and generating, with the processor, the workpiece image based on the electrons received by the detector as the electron beam is scanned across the workpiece may comprise generating a plurality of workpiece images based on the electrons received by the detector as the electron beam is scanned across each of the plurality of workpiece sites.

In some embodiments, the steps of determining the size and location of each ROI of the workpiece and determining the groups of ROIs having similar size may be performed in parallel to the step of generating the plurality of workpiece images.

In some embodiments, before directing, with the beam deflector, the electron beam onto the location of each ROI of the first ROI group, the method may further comprise performing a first image setup process for the first ROI group. Performing the first image setup process for the first ROI group may comprise transmitting a first scanning pattern to the beam deflector based on the size of each ROI of the first ROI group, and the beam deflector may be configured to direct the electron beam onto the location of each ROI of the first ROI group according to the first scanning pattern.

In some embodiments, before directing, with the beam deflector, the electron beam onto the location of each ROI of the second ROI group, the method further may comprise performing a second image setup process the second ROI group. Performing the second image setup process for the second ROI group may comprise transmitting a second scanning pattern to the beam deflector based on the size of each ROI of the second ROI group, and the beam deflector may be configured to direct the electron beam onto the location of each ROI of the second ROI group according to the second scanning pattern.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of an apparatus according to an embodiment of the present disclosure;

FIG. 2A is a top view of a workpiece according to an embodiment of the present disclosure;

FIG. 2B is a top view of a workpiece according to another embodiment of the present disclosure;

FIG. 3 is a flowchart of a method according to an embodiment of the present disclosure;

FIG. 4 is a flowchart of a method according to another embodiment of the present disclosure;

FIG. 5 is a flowchart of a method according to another embodiment of the present disclosure;

FIG. 6 is a flowchart of a method according to another embodiment of the present disclosure;

FIG. 7 is a flowchart of a method according to another embodiment of the present disclosure;

FIG. 8 is a flowchart of a method according to another embodiment of the present disclosure; and

FIG. 9 is a diagram of a system according to an embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

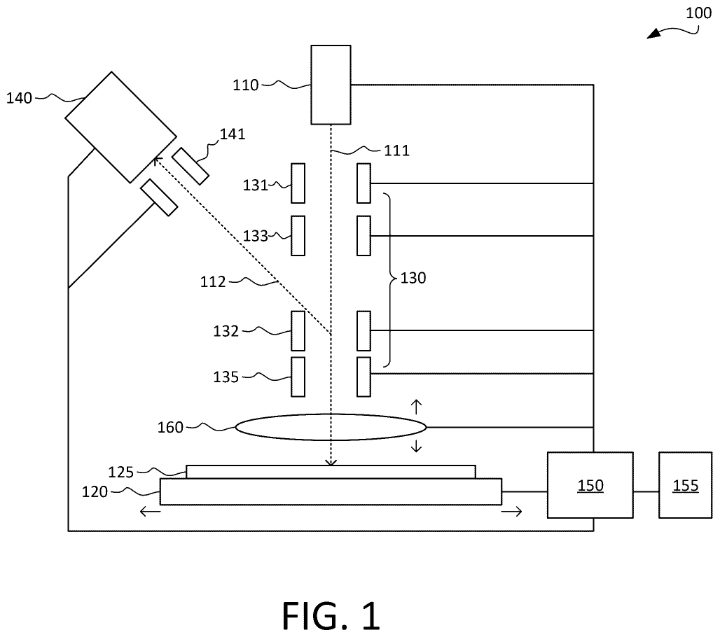

An embodiment of the present disclosure provides an apparatus 100, as shown in FIG. 1. The apparatus 100 may be an inspection tool such as, for example, a scanning electron microscope (SEM) or the like.

The apparatus 100 may comprise an electron source 110. The electron source 110 may be configured to generate an electron beam 111.

The apparatus 100 may further comprise a stage 120. The stage 120 may be configured to hold a workpiece 125 in the path of the electron beam 111. The workpiece 125 may be a semiconductor wafer, coupon wafer (i.e., a workpiece having two or three printed dies adhered on top of a dummy wafer), substrate, PCB, flat panel display, or the like or any other type of workpiece. The workpiece 125 may include a plurality of regions of interest (ROIs). An ROI may be, for example, a fin, channel, hole, slit, trench, etch, or other feature of the workpiece 125 and is not limited herein. The stage 120 may include one or more motors or actuators configured to move the workpiece 125 in on or more in plane directions (e.g., X direction and Y direction) or out of plane direction (e.g., Z direction) relative to the electron beam 111. The stage 120 may have a positive bias so as to attract electrons from the electron beam 111 directed onto the workpiece 125.

The apparatus 100 may further comprise a beam deflector 130. The beam deflector 130 may be disposed in the path of the electron beam 111 between the electron source 110 and the stage 120. The beam deflector 130 may be configured to direct the path of the electron beam 111 onto a specified location of the workpiece 125 (e.g., an ROI). For example, the beam deflector 130 may comprise an upper main field deflector 131 and an upper sub field deflector 133. The upper main field deflector 131 and the upper sub field deflector 133 may be configured to produce an electrostatic field or an electromagnetic field control the path of the electron beam 111. By adjusting a voltage and current of the upper main field deflector 131, the electrostatic field or the electromagnetic field may affect the electron beam 111 differently, thereby directing the electron beam 111 onto different locations of the workpiece 125. By adjusting a voltage of the upper sub field deflector 133, the electron beam 111 can be controlled to move within a precise area of the workpiece 125, (e.g., within an ROI and between ROIs). The voltage and current applied to the upper main field deflector 131 can remain constant while adjusting a voltage of the upper sub field deflector 133. With voltage-based deflection of the upper sub field deflector 133, the time to navigate between ROIs may be reduced compared to current-based deflection, thereby reducing processing time and increasing throughput.

The apparatus 100 may further comprise a detector 140. The detector 140 may be configured to receive electrons 112 (e.g., secondary electrons and/or back-scattered electrons) formed when the electron beam 111 impacts the workpiece 125 on the stage 120. To compensate for the adjustment of the upper main field deflector 131 and the upper sub field deflector 133, the beam deflector 130 may further comprise a lower main field deflector 132 and a lower sub field deflector 135, which may be configured to direct the electrons 112 onto the detector 140. In some embodiments, the lower main field deflector 132 and the lower sub field deflector 135 may be configured as a Wein filter mechanism. For example, by adjusting a voltage or current of the upper main field deflector 131, a corresponding adjustment of a voltage or current of the lower main field deflector 132 may be made to direct the electrons 112 onto the detector 140. To avoid an unintended deflection to the electron beam 111, opposite voltage and current may be applied to the upper main field deflector 131 with respect to lower main field deflector 132. In addition, by adjusting a voltage of the upper sub field deflector 133 to navigate between ROIs or within an ROI, a corresponding adjustment of a voltage of the lower sub field deflector 135 can be made to direct the electrons 112 formed from interaction with the workpiece 125. An opposite voltage may be applied to the upper sub field deflector 133 with respect to lower sub field deflector 135 to match deflection of the electron beam 111 with placement of electrons 112 on the detector 140. The lower main field deflector 132 and the lower sub field deflector 135 may maintain an equal and opposite electric and magnetic field mutually perpendicular to each other, which does not disturb the electron beam 111 traveling toward the workpiece 125, but deflects the electrons 112 toward the detector 140. In some embodiments, a descan deflector 141 may be provided in the path of the electrons 112 prior to the detector 140, which can produce an electrostatic field or an electromagnetic field to direct the electrons 112 relative to the center of the detector 140.

The apparatus 100 may further comprise a processor 150. The processor 150 may include a microprocessor, a microcontroller, FPGA, or other devices.

The processor 150 may be coupled to the components of the apparatus 100 in any suitable manner (e.g., via one or more transmission media, which may include wired and/or wireless transmission media) such that the processor 150 can receive output. The processor 150 may be configured to perform a number of functions using the output. An inspection tool can receive instructions or other information from the processor 150. The processor 150 optionally may be in electronic communication with another inspection tool, a metrology tool, a repair tool, or a review tool (not illustrated) to receive additional information or send instructions.

The processor 150 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 150 may be disposed in or otherwise part of the apparatus 100 or another device. In an example, the processor 150 and may be part of a standalone control unit or in a centralized quality control unit. Multiple processors 150 may be used, defining multiple subsystems of the apparatus 100.

The processor 150 may be implemented in practice by any combination of hardware, software, and firmware. Also, its functions as described herein may be performed by one unit, or divided up among different components, each of which may be implemented in turn by any combination of hardware, software and firmware. Program code, instructions, configuration data, lookup tables, calibration data, and algorithms, etc. for the processor 150 to implement various methods and functions may be stored in readable storage media, such as a memory.

If the apparatus 100 includes more than one subsystem, then the different processors 150 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 150 may be configured to perform a number of functions using the output of the apparatus 100 or other output. For instance, the processor 150 may be configured to send the output to an electronic data storage unit or another storage medium. The processor 150 may be further configured as described herein.

The processor 150 may be configured according to any of the embodiments described herein. The processor 150 also may be configured to perform other functions or additional steps using the output of the apparatus 100 or using images or data from other sources.

The processor 150 may be communicatively coupled to any of the various components or sub-systems of apparatus 100 in any manner known in the art. Moreover, the processor 150 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 150 and other subsystems of the apparatus 100 or systems external to apparatus 100. Various steps, functions, and/or operations of apparatus 100 and the methods disclosed herein are carried out by one or more of the following: electronic circuits, logic gates, multiplexers, programmable logic devices, ASICs, FPGAs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, PCB trace, or wireless transmission link. For instance, the various steps described throughout the present disclosure may be carried out by a single processor 150 (or computer subsystem) or, alternatively, multiple processors 150 (or multiple computer subsystems). Moreover, different sub-systems of the apparatus 100 may include one or more computing or logic systems. Therefore, the above description should not be interpreted as a limitation on the present disclosure but merely an illustration.

The processor 150 may be in electronic communication with the electron source 110. For example, the processor 150 may be configured to send instructions to the electron source 110 to generate the electron beam 111.

The processor 150 may be in electronic communication with the stage 120. For example, the processor 150 may be configured to send instructions to the one or more motors or actuators of the stage 120 to cause the stage 120 to move relative to the electron beam 111, such that the electron beam 111 is scanned across the workpiece 125 to a particular ROI.

The processor 150 may be in electronic communication with the beam deflector 130. For example, the processor 150 may be configured to send instructions to the beam deflector 130 to adjust a voltage or current applied to the upper main field deflector 131 and the lower main field deflector 132 to direct the electron beam 111 onto the workpiece 125 and to direct the electrons 112 onto the detector 140. The processor 150 may be further configured to send instructions to the beam deflector 130 to adjust a voltage applied to the upper sub field deflector 133 and the lower sub field deflector 135 to scan the electron beam 111 within a region of the workpiece 125 (e.g., a 120 μm×120 μm region) or between ROIs and direct the electrons 112 onto the detector 140. The processor may be further configured to send instructions to the descan deflector 141 to adjust voltage such that that the electrons 112 land around the center of the detector 140 after corresponding deflections of the electron beam 111.

The processor 150 may be in electronic communication with the detector 140. For example, the processor 150 may be configured to generate a workpiece image based on the electrons 112 received by the detector 140 as the electron beam 111 is scanned across the workpiece 125. In some embodiments, the workpiece 125 may comprise a plurality of workpiece sites 128, and the processor 150 may be configured to generate a plurality of workpiece images based on the electrons 112 received by the detector as the electron beam 111 is scanned across each of the plurality of workpiece sites 128.

The processor 150 may be configured to determine a size and location of each ROI of the workpiece 125. For example, the processor 150 may perform image processing on the workpiece image to identify the location of each ROI and the size of each ROI of the workpiece, according to the workpiece image. In some embodiments where the processor 150 generates a plurality of workpiece images, the processor 150 may perform image processing on the plurality of workpiece images to identify the location of each ROI and the size of each ROI of the workpiece, according to the plurality of workpiece images.

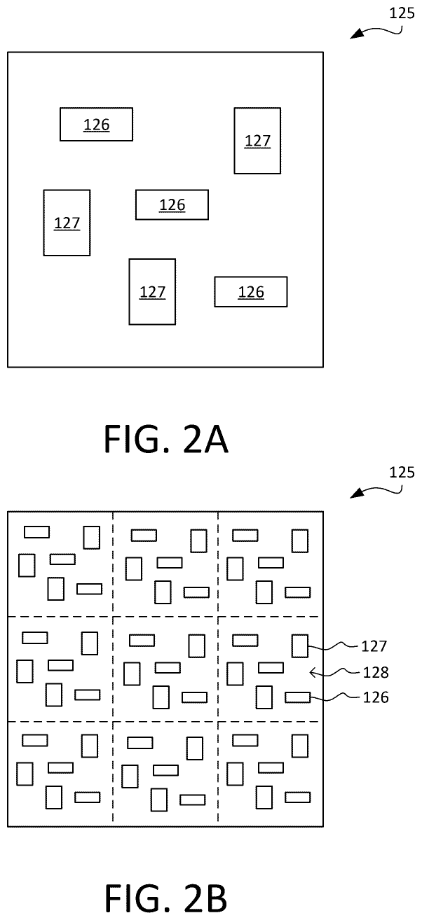

The processor 150 may be further configured to determine groups of ROIs having similar size based on the size of each ROI of the workpiece 125. For example, the groups of ROIs may comprise a first ROI group 126 and a second ROI group 127, each comprising a plurality of ROIs. As shown in FIG. 2A, each ROI in the first ROI group 126 may be of similar size, and each ROI in the second ROI group 127 may be of similar size. As further shown in FIG. 2B, each of the plurality of workpiece sites 128 may comprise a plurality of ROIs and may include ROIs of the first ROI group 126 and ROIs of the second ROI group 127.

The processor 150 may be in electronic communication with a memory 155. In some embodiments, a deep learning segmentation algorithm may be stored on the memory 155. The processor 150 may be configured to segment each ROI of the workpiece 125 from a given workpiece image, determine the size and location of each ROI, and determine the groups of ROIs based on size using the deep learning segmentation algorithm. The deep learning segmentation algorithm may be designed in such a way that algo border pixels may not be needed at edge of image which can avoid over scanning and reduce scan time. The deep learning segmentation algorithm can be trained based on the type of workpiece 125 and types of ROIs of the workpiece 125, and by applying the deep learning segmentation algorithm to the image of the workpiece, the processor 150 can efficiently locate and group ROIs on the workpiece 125.

In some embodiments, at least one design image may be stored on the memory 155. The processor 150 may be configured to determine the size and location of each ROI of the workpiece 125 and determine the groups of ROIs based on the workpiece image and the at least one design image. The at least one design image may be a computer aided design (CAD) drawing or rendering of the workpiece 125. The processor 150 may select a design image corresponding to the type of workpiece 125 or compare the workpiece image to a plurality of design images to identify a design image most similar to the workpiece image. The processor 150 may compare the design image to the workpiece image to efficiently locate and group ROIs on the workpiece 125.

In some embodiments, the processor 150 may use the at least one design image to determine the size and location of each ROI of the workpiece 125 and determine the groups of ROIs instead of generating the workpiece image, which can further reduce processing time and increase throughput.

In some embodiments where the workpiece 125 comprises a plurality of workpiece sites 128, the processor 150 may be configured to determine the size and location of each ROI of the workpiece 125 and determine the groups of ROIs in parallel to generating the plurality of workpiece images. For example, after the processor 150 generates a first workpiece image corresponding to one of the workpiece sites, the processor 150 may determine the size and location of each ROI in the first workpiece image while the processor 150 continues to generate additional workpiece images of the other workpiece sites. Thus, processing time can be reduced, thereby increasing throughput.

The processor 150 may be further configured to send instructions to the beam deflector 130 to direct the electron beam 111 onto the location of each ROI of the first ROI group 126. For example, the processor 150 may send instructions to the beam deflector 130 to adjust a voltage of the upper sub field deflector 133 and the lower sub field deflector 135 while the voltage and current applied to the upper main field deflector 131 and the lower main field deflector 132 remain constant, such that the electron beam 111 is directed onto each ROI of the first ROI group 126 and the electrons 112 are directed to the detector 140. The processor 150 may be further configured to generate a first ROI image based on the electrons 112 received by the detector 140 as the electron beam 111 is scanned across each ROI of the first ROI group 126.

The processor 150 may be further configured to send instructions to the beam deflector 130 to direct the electron beam 111 onto the location of each ROI of the second ROI group 127. For example, the processor 150 may send instructions to the beam deflector 130 to adjust a voltage of the upper sub field deflector 133 and the lower sub field deflector 135 while the voltage and current applied to the upper main field deflector 131 and the lower main field deflector 132 remain constant, such that the electron beam 111 is directed onto each ROI of the second ROI group 127 and the electrons 112 are directed to the detector 140. The processor 150 may be further configured to generate a second ROI image based on the electrons 112 received by the detector 140 as the electron beam is scanned across each ROI of the second ROI group 127.

The first ROI image and the second ROI image may be higher resolution images compared to the workpiece image. Accordingly, the workpiece image may be a fast image scan to identify the ROIs of the workpiece 125, while the first ROI image and the second ROI image are slower, high-resolution images that may be used for inspection of the ROIs, and time spent processing areas outside of the ROIs is reduced. In some embodiments, the processor 150 may be configured to stitch together the first ROI image and the second ROI image into a single image.

In some embodiments, the electron beam 111 may be scanned within only a center portion of the ROI. For example, an area of 3×3 pixels within each ROI can be scanned instead of scanning the entire ROI (which may be 10×10 pixels or more), which can further reduce processing time and increase throughput.

In some embodiments, the groups of ROIs may comprise more than two groups of ROIs. The processor 150 may be further configured to send instructions to the beam deflector 130 to direct the electron beam 111 onto the location of each ROI of the additional groups of ROIs and generate additional ROI images based on the electrons 112 received by the detector 140 as the electron beam 111 is scanned across each ROI of the additional groups of ROIs, until images of all ROIs of the workpiece 125 are generated.

The apparatus 100 may further comprise an objective lens 160. The objective lens 160 may be configured to control the focus of the electron beam 111, for example, by adjusting a position of the objective lens 160 along the path of the electron beam 111. The position of the objective lens 160 may be adjusted directly with one or more motors or actuators. Alternatively, the position of the objective lens 160 may be adjusted indirectly by moving the stage 120 relative to the objective lens 160. The processor 150 may be configured to send instructions to move the objective lens 160 or the stage 120 to adjust the focus of the electron beam 111.

The processor 150 may be configured to perform image setup for each group of ROIs. For example, image setup may comprise a first image setup process for the first ROI group and a second image process for the second ROI group. Each image setup process may comprise one or more tasks. For example, after the current applied to the upper main field deflector 131 and the lower main field deflector 132 is adjusted, a settling time may be provided to allow position of the electron beam 111 to settle before imaging. Furthermore, a scanning pattern can be transmitted from the processor 150 to the beam deflector 130 based on the size of each ROI in a particular group of ROIs. For example, the first image setup process may comprise transmitting a first scanning pattern to the beam deflector 130 based on the size of each ROI of the first ROI group, and the second image setup process may comprise transmitting a second scanning pattern to the beam deflector 130 based on the size of each ROI of the second ROI group. The beam deflector 130 may use the first scanning pattern to control the adjustment of the voltage applied to the upper sub field deflector 133 and the lower sub field deflector 135 to navigate the electron beam 111 between each ROI of the first ROI group, and the beam deflector 130 may use the second scanning pattern to control the adjustment of the voltage applied to the upper sub field deflector 133 and the lower sub field deflector 135 to navigate the electron beam 111 between each ROI of the second ROI group. The image setup process may further comprise transmitting an amount of pixels to expect from a scan or an amount of pixels to expect for image processing to the detector 140 based on the size of each ROI in each ROI group. By performing image setup once per group of ROIs (instead of for every ROI), overall time for image setup can be reduced, since only the voltage applied to the upper sub field deflector 133 and the lower sub field deflector 135 is adjusted to navigate the electron beam 111 to each ROI within the ROI group while other parameters remain constant, thereby reducing processing time and increasing throughput.

With the apparatus 100, ROIs of the workpiece 125 are grouped based on size to improve the selective scanning process of the workpiece 125 by reducing processing time and increasing throughput by 5 times to 25 times.

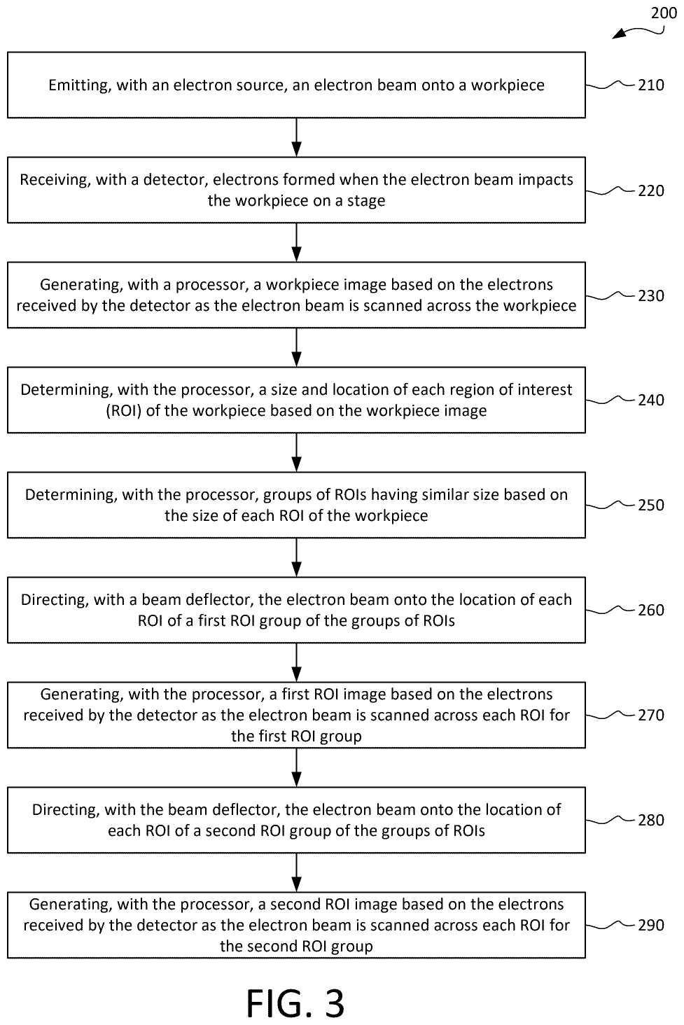

Another embodiment of the present disclosure provides a method 200. As shown in FIG. 3, the method 200 may comprise the following steps.

At step 210, an electron source emits an electron beam onto a workpiece. The workpiece may be disposed on a stage. The workpiece may be a semiconductor wafer, substrate, PCB, flat panel display, or the like or any other type of workpiece. The workpiece may include a plurality of regions of interest (ROIs).

At step 220, a detector receives electrons (e.g., secondary electrons and/or back-scattered electrons) formed when the electron beam impacts the workpiece on the stage.

At step 230, a processor generates a workpiece image based on the electrons received by the detector as the electron beam is scanned across the workpiece.

At step 240, the processor determines a size and location of each region of interest (ROI) of the workpiece based on the workpiece image.

At step 250, the processor determines groups of ROIs having similar size based on the size of each ROI of the workpiece. The groups of ROIs may comprise a first ROI group and a second ROI group. Each of the first ROI group and the second ROI group may comprise a plurality of ROIs. The groups of ROIs may comprise additional groups depending on the number of ROIs of the workpiece and number of unique sizes of the ROIs.

At step 260, a beam deflector directs the electron beam onto the location of each ROI of the first ROI group. For example, the beam deflector may generate an electrostatic field or an electromagnetic field which alters the path of the electron beam.

At step 270, the processor generates a first ROI image based on the electrons received by the detector as the electron beam is scanned across each ROI of the first ROI group.

At step 280, the beam deflector directs the electron beam onto the location of each ROI of the second ROI group.

At step 290, the processor generates a second ROI image based on the electrons received by the detector as the electron beam is scanned across each ROI of the second ROI group.

In some embodiments, the groups of ROIs may comprise more than two groups of ROIs. Accordingly, steps 280 and 290 may be repeated to direct the electron beam onto the location of each ROI of the additional groups of ROIs (e.g., third ROI group, fourth ROI group, etc.) and generate additional ROI images (e.g., third ROI image, fourth ROI image, etc.) based on the electrons received by the detector as the electron beam is scanned across each ROI of the additional groups of ROIs, until image of all ROIs of the workpiece are generated.

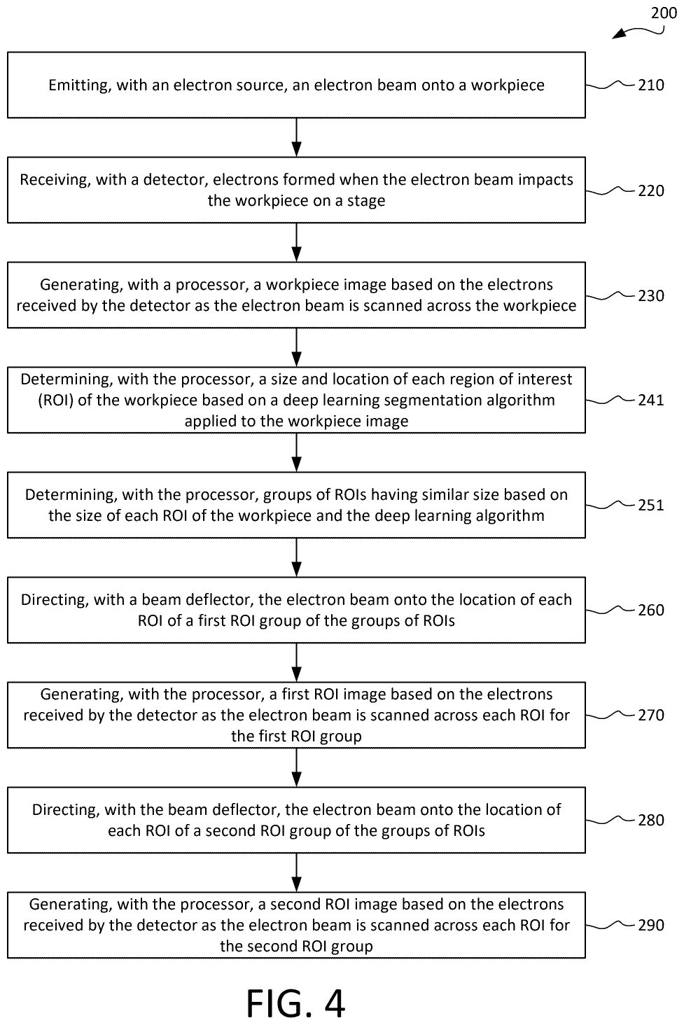

In some embodiments, the processor may use a deep learning segmentation algorithm to determine the size and location of each ROI of the workpiece and to determine groups of ROIs having similar size. Specifically, step 240 and step 250 may comprise step 241 and 251, respectively, as shown in FIG. 4. At step 241, the processor determines the size and location of each ROI of the workpiece based on the deep learning segmentation algorithm applied to the workpiece image. At step 251, the processor determines groups of ROIs having similar size based on the size of each ROI of the workpiece and the deep learning segmentation algorithm. The deep learning segmentation algorithm can be trained based on the type of workpiece and types of ROIs on the workpiece, such that the processor can efficiently locate and group ROIs on the workpiece from the workpiece image.

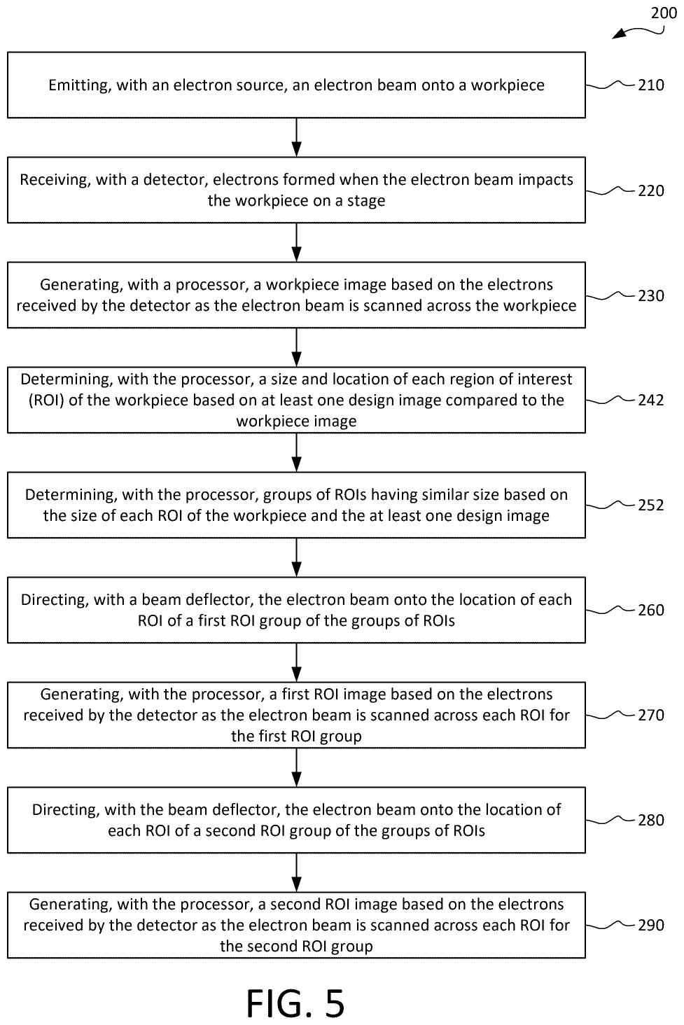

In some embodiments, the processor may use at least one design image to determine the size and location of each ROI of the workpiece and to determine groups of ROIs having similar size. Specifically, step 240 and step 250 may comprise step 242 and step 252, respectively, as shown in FIG. 5. At step 242, the processor determines the size and location of each ROI of the workpiece based on the at least one design image compared to the workpiece image. At step 252, the processor determines groups of ROIs having similar size based on the size of each ROI of the workpiece and the at least one design image. The at least one design image may be a computer aided design (CAD) drawing or rendering of the workpiece. The processor may select a design image corresponding to the type of workpiece or compare the workpiece image to a plurality of design images to identify a design image most similar to the workpiece image, such that the processor can efficiently locate and group ROIs on the workpiece from the workpiece image.

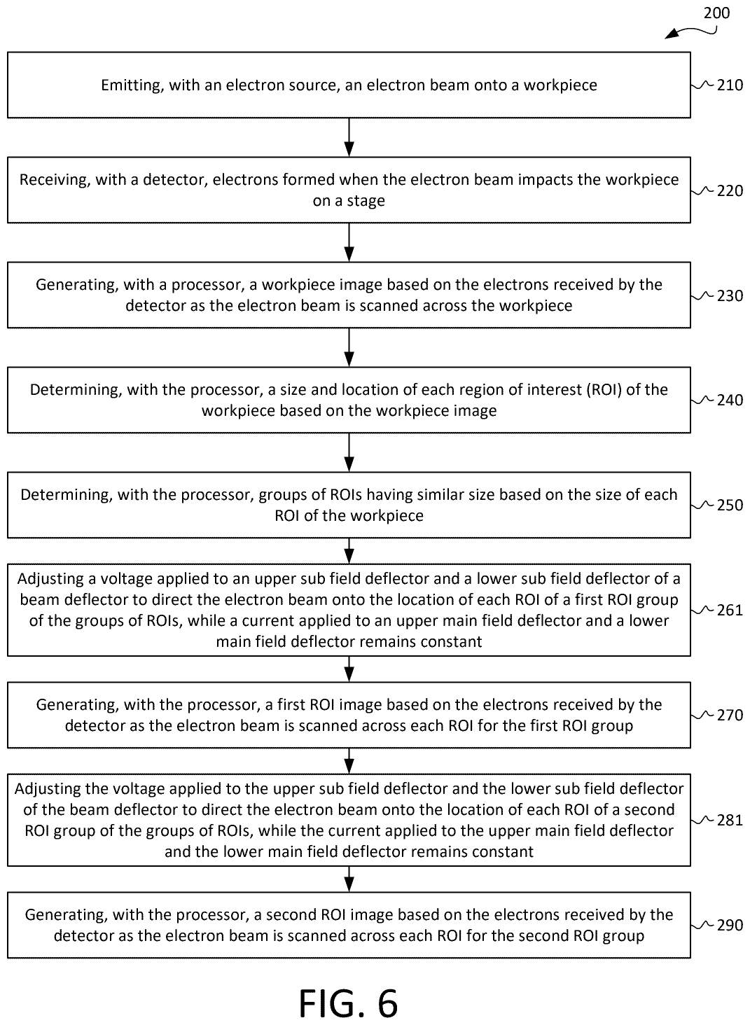

In some embodiments, the beam deflector may comprise an upper main field deflector, an upper sub field deflector, a lower main field deflector, and a lower sub field deflector. The upper main field deflector and the upper sub field deflector may be configured to direct the electron beam onto the workpiece, and the lower main field deflector and the lower sub field deflector may be configured to direct the electrons onto the detector. By adjusting a voltage and current of the upper main field deflector, the electrostatic field or the electromagnetic field may affect the electron beam differently, thereby directing the electron beam onto different locations of the workpiece, and a corresponding adjustment of the voltage and current of the lower main field deflector can direct the electrons to be received by the detector. By adjusting the voltage of the upper sub field deflector, the electron beam can be directed to impact different locations of the workpiece (e.g., within an ROI or between ROIs), and a corresponding adjustment of the voltage of the lower sub field deflector can direct the electrons to be received by the detector. In other words, the upper main field deflector and the lower main field deflector can be used for macro-level movements of the electron beam, while the upper sub field deflector and the lower sub field deflector can be used for a detail-level movement of the electron beam. The current applied to the upper main field deflector and the lower main field deflector can remain constant while voltage adjustments are made to the upper sub field deflector and the lower sub field deflector. Accordingly, step 260 and step 280 may comprise step 261 and 281, respectively, as shown in FIG. 6. At step 261, the voltage applied to the upper sub field deflector and the lower sub field deflector of the beam deflector is adjusted to direct the electron beam onto the location of each ROI of the first ROI group, while the current applied to the upper main field deflector and the lower main field deflector remain constant. At step 281, the voltage applied to the upper sub field deflector and the lower sub field deflector of the beam deflector is adjusted to direct the electron beam onto the location of each ROI of the second ROI group, while the current applied to the upper main field deflector and the lower main field deflector remain constant. With voltage-based deflection of the upper sub field deflector and the lower sub field deflector, the time to navigate between ROIs may be reduced compared to current-based deflection of the upper main field deflector and the lower main field deflector, thereby reducing processing time and increasing throughput.

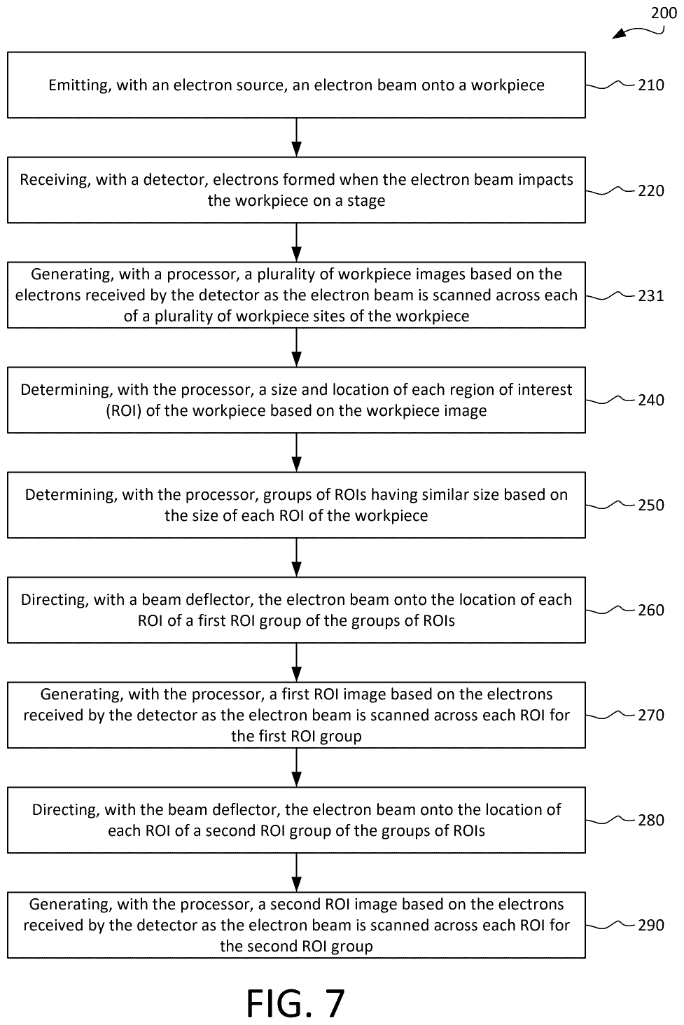

In some embodiments, the workpiece may be divided into a plurality of workpiece sites. For example, each workpiece site may comprise a plurality of ROIs, and a single workpiece image may be unable to identify all of the ROIs based on its low resolution. Thus, to improve ROI recognition, separate workpiece images can be taken at each workpiece site. Specifically, step 230 may comprise step 231, as shown in FIG. 7. At step 231, the processor generates a plurality of workpiece images based on the electrons received by the detector as the electron beam is scanned across each of the plurality of workpiece sites of the workpiece. The number of workpiece images may correspond to the number of workpiece sites. The processor may be configured to determine the size and location of each ROI of the workpiece and determine groups of ROIs having similar size in parallel to generating the plurality of workpiece images. In other words, after the processor generates a workpiece image corresponding to one of the workpiece sites, the processor may determine the size and location of each ROI in the workpiece image of the one workpiece site and determine groups of ROIs having similar size while the processor continues to generate additional workpiece images of the other workpiece sites. Thus, by performing step 240 and 250 in parallel to step 231, processing time can be reduced, thereby increasing throughput.

In some embodiments, the focus of the electron beam may be controlled by an objective lens. By adjusting the position of the objective lens relative to the stage, the focus of the electron beam can be adjusted.

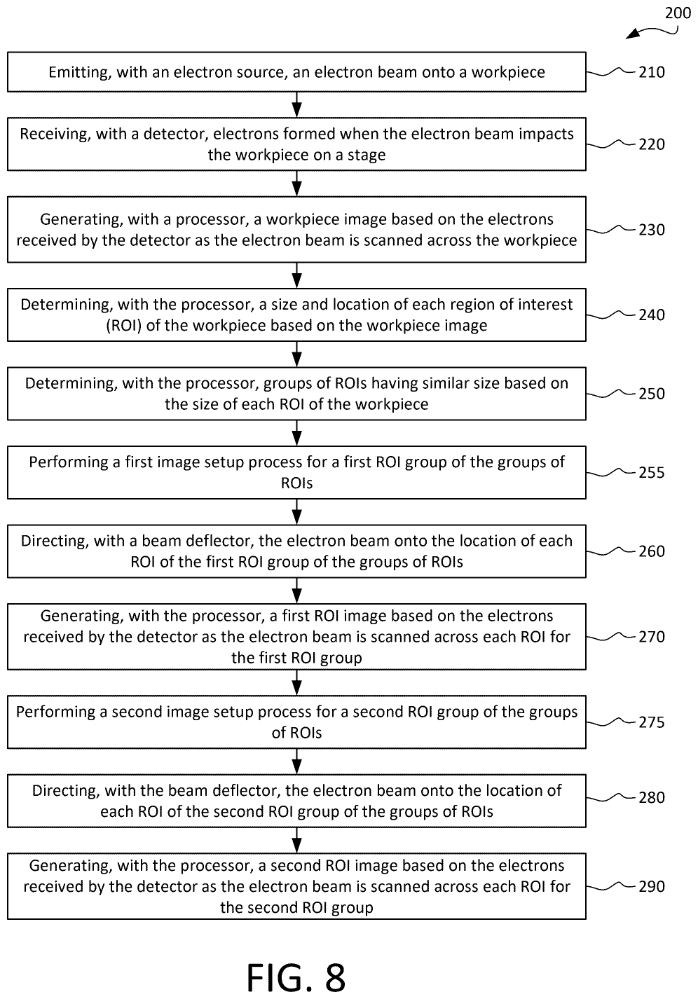

In some embodiments, image setup may be performed for each group of ROIs. For example, the method 200 may further comprise step 255 and 275, as shown in FIG. 8. At step 255, a first image setup process is performed for the first ROI group. Step 255 may be performed before step 260. At step 275, a second image setup process is performed for the second ROI group. Step 275 may be performed before step 280. Each image setup process may comprise one or more tasks. For example, after the current applied to the upper main field deflector and the lower main field deflector is adjusted, a settling time may be provided to allow position of the electron beam to settle before imaging. Furthermore, a scanning pattern can be transmitted from to the beam deflector based on the size of each ROI in a particular group of ROIs. For example, the first image setup process may comprise transmitting a first scanning pattern to the beam deflector based on the size of each ROI of the first ROI group, and the second image setup process may comprise transmitting a second scanning pattern to the beam deflector based on the size of each ROI of the second ROI group. The beam deflector may use the first scanning pattern to control the adjustment of the voltage applied to the upper sub field deflector and the lower sub field deflector to navigate the electron beam between each ROI of the first ROI group, and the beam deflector may use the second scanning pattern to control the adjustment of the voltage applied to the upper sub field deflector and the lower sub field deflector to navigate the electron beam between each ROI of the second ROI group. The image setup process may further comprise transmitting an amount of pixels to expect from a scan or an amount of pixels to expect for image processing to the detector based on the size of each ROI in each ROI group. By performing image setup once per group of ROIs (instead of for every ROI), overall time for image setup can be reduced, since only the voltage applied to the upper sub field deflector and the lower sub field deflector are adjusted to navigate the electron beam to each ROI within the ROI group while other parameters remain constant, thereby reducing processing time and increasing throughput.

With the method 200, ROIs of the workpiece are grouped based on size to improve the selective scanning process of the workpiece by reducing processing time and increasing throughput by 5 times to 25 times.

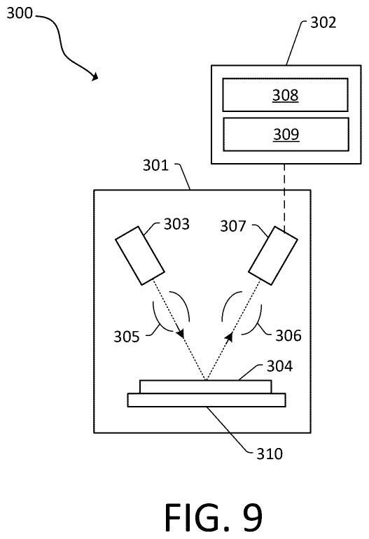

Another embodiment of the present disclosure provides a system 300, as shown in FIG. 9. The system 300 includes a wafer inspection tool (which includes the electron column 301) configured to generate images of a wafer 304. For example, the wafer inspection tool may be an embodiment of the apparatus 100 described herein.

The wafer inspection tool includes an output acquisition subsystem that includes at least an energy source and a detector. The output acquisition subsystem may be an electron beam-based output acquisition subsystem. For example, in one embodiment, the energy directed to the wafer 304 includes electrons, and the energy detected from the wafer 304 includes electrons. In this manner, the energy source may be an electron beam source. In one such embodiment shown in FIG. 6, the output acquisition subsystem includes electron column 301, which is coupled to computer subsystem 302. A stage 310 may hold the wafer 304.

As also shown in FIG. 9, the electron column 301 includes an electron beam source 303 configured to generate electrons that are focused to wafer 304 by one or more elements 305. The electron beam source 303 may include, for example, a cathode source or emitter tip. The one or more elements 305 may include, for example, a gun lens, an anode, a beam limiting aperture, a gate valve, a beam current selection aperture, an objective lens, and a scanning subsystem, all of which may include any such suitable elements known in the art.

Electrons returned from the wafer 304 (e.g., electrons and/or back-scattered electrons) may be focused by one or more elements 306 to detector 307. One or more elements 306 may include, for example, a scanning subsystem, which may be the same scanning subsystem included in element(s) 305.

The electron column 301 also may include any other suitable elements known in the art.

Although the electron column 301 is shown in FIG. 9 as being configured such that the electrons are directed to the wafer 304 at an oblique angle of incidence and are scattered from the wafer 304 at another oblique angle, the electron beam may be directed to and scattered from the wafer 304 at any suitable angles. In addition, the electron beam-based output acquisition subsystem may be configured to use multiple modes to generate images of the wafer 304 (e.g., with different illumination angles, collection angles, etc.). The multiple modes of the electron beam-based output acquisition subsystem may be different in any image generation parameters of the output acquisition subsystem.

Computer subsystem 302 may be coupled to detector 307 as described above. The detector 307 may detect electrons returned from the surface of the wafer 304 thereby forming electron beam images of the wafer 304. The electron beam images may include any suitable electron beam images. Computer subsystem 302 may be configured to perform any of the functions described herein using the output of the detector 307 and/or the electron beam images. Computer subsystem 302 may be configured to perform any additional step(s) described herein. A system 300 that includes the output acquisition subsystem shown in FIG. 9 may be further configured as described herein.

It is noted that FIG. 9 is provided herein to generally illustrate a configuration of an electron beam-based output acquisition subsystem that may be used in the embodiments described herein. The electron beam-based output acquisition subsystem configuration described herein may be altered to optimize the performance of the output acquisition subsystem as is normally performed when designing a commercial output acquisition system. In addition, the systems described herein may be implemented using an existing system (e.g., by adding functionality described herein to an existing system). For some such systems, the methods described herein may be provided as optional functionality of the system (e.g., in addition to other functionality of the system). Alternatively, the system described herein may be designed as a completely new system.

Although the output acquisition subsystem is described above as being an electron beam-based output acquisition subsystem, the output acquisition subsystem may be an ion beam-based output acquisition subsystem. Such an output acquisition subsystem may be configured as shown in FIG. 9 except that the electron beam source may be replaced with any suitable ion beam source known in the art. In addition, the output acquisition subsystem may be any other suitable ion beam-based output acquisition subsystem such as those included in commercially available focused ion beam (FIB) systems, helium ion microscopy (HIM) systems, and secondary ion mass spectroscopy (SIMS) systems.

The computer subsystem 302 includes a processor 308 and an electronic data storage unit 309. The processor 308 may include a microprocessor, a microcontroller, or other devices.

The computer subsystem 302 may be coupled to the components of the system 300 in any suitable manner (e.g., via one or more transmission media, which may include wired and/or wireless transmission media) such that the processor 308 can receive output. The processor 308 may be configured to perform a number of functions using the output. The wafer inspection tool can receive instructions or other information from the processor 308. The processor 308 and/or the electronic data storage unit 309 optionally may be in electronic communication with another wafer inspection tool, a wafer metrology tool, or a wafer review tool (not illustrated) to receive additional information or send instructions.

The processor 308 is in electronic communication with the wafer inspection tool, such as the detector 307. The processor 308 may be configured to process images generated using measurements from the detector 307. For example, the processor may perform embodiments of the method 200 described herein.

The computer subsystem 302, other system(s), or other subsystem(s) described herein may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 308 and electronic data storage unit 309 may be disposed in or otherwise part of the system 300 or another device. In an example, the processor 308 and electronic data storage unit 309 may be part of a standalone control unit or in a centralized quality control unit. Multiple processors 308 or electronic data storage units 309 may be used.

The processor 308 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 308 to implement various methods and functions may be stored in readable storage media, such as a memory in the electronic data storage unit 309 or other memory.

If the system 300 includes more than one computer subsystem 302, then the different subsystems may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 308 may be configured to perform a number of functions using the output of the system 300 or other output. For instance, the processor 308 may be configured to send the output to an electronic data storage unit 309 or another storage medium. The processor 308 may be further configured as described herein.

The processor 308 or computer subsystem 302 may be part of a defect review system, an inspection system, a metrology system, or some other type of system. Thus, the embodiments disclosed herein describe some configurations that can be tailored in a number of manners for systems having different capabilities that are more or less suitable for different applications.

The processor 308 may be configured according to any of the embodiments described herein. The processor 308 also may be configured to perform other functions or additional steps using the output of the system 300 or using images or data from other sources.

The processor 308 may be communicatively coupled to any of the various components or sub-systems of system 300 in any manner known in the art. Moreover, the processor 308 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 308 and other subsystems of the system 300 or systems external to system 300.

Various steps, functions, and/or operations of system 300 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor 308 (or computer subsystem 302) or, alternatively, multiple processors 308 (or multiple computer subsystems 302). Moreover, different sub-systems of the system 300 may include one or more computing or logic systems. Therefore, the above description should not be interpreted as a limitation on the present disclosure but merely an illustration.

With the system 300, ROIs of the workpiece are grouped based on size to improve the selective scanning process of the workpiece by reducing processing time and increasing throughput by 5 times to 25 times.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an electron source configured to generate an electron beam;
a stage configured to hold a workpiece in a path of the electron beam;
a beam deflector disposed in the path of the electron beam between the electron source and the stage;
a detector configured to receive electrons formed when the electron beam impacts the workpiece on the stage; and
a processor configured to:
generate a workpiece image based on the electrons received by the detector as the electron beam is scanned across the workpiece;
determine a size and location of each region of interest (ROI) of the workpiece based on the workpiece image;
determine groups of ROIs having similar size based on the size of each ROI of the workpiece, wherein the groups of ROIs comprise a first ROI group and a second ROI group, each comprising a plurality of ROIs;
send instructions to the beam deflector to direct the electron beam onto the location of each ROI of the first ROI group;
generate a first ROI image based on the electrons received by the detector as the electron beam is scanned across each ROI of the first ROI group;
send instructions to the beam deflector to direct the electron beam onto the location of each ROI of the second ROI group; and
generate a second ROI image based on the electrons received by the detector as the electron beam is scanned across each ROI of the second ROI group.

2. The system of claim 1, further comprising a memory in electronic communication with the processor, wherein a deep learning segmentation algorithm is stored on the memory, and the processor is configured to determine the size and location of each ROI of the workpiece and determine the groups of ROIs based on the deep learning segmentation algorithm.

3. The system of claim 1, further comprising a memory in electronic communication with the processor, wherein at least one design image is stored on the memory, and the processor is configured to determine the size and location of each ROI of the workpiece and determine the groups of ROIs based on the at least one design image.

4. The system of claim 1, wherein the beam deflector comprises an upper main field deflector, an upper sub field deflector, a lower main field deflector, and a lower sub field deflector, and the beam deflector is configured to direct the electron beam onto the location of each ROI by adjusting a voltage applied to the upper sub field deflector and the lower sub field deflector, while a current applied to the upper main field deflector and the lower main field deflector remains constant.

5. The system of claim 1, wherein the workpiece is divided into a plurality of workpiece sites, and the processor is configured to generate a plurality of workpiece images based on the electrons received by the detector as the electron beam is scanned across each of the plurality of workpiece sites.

6. The system of claim 5, wherein the processor is configured to determine the size and location of each ROI of the workpiece and determine the groups of ROIs having similar size in parallel with generating the plurality of workpiece images corresponding to each of the plurality of workpiece sites.

7. The system of claim 1, wherein the processor is further configured to:
perform a first image setup process for the first ROI group; and
perform a second image setup process for the second ROI group.

8. The system of claim 7, wherein the first image setup process comprises transmitting a first scanning pattern to the beam deflector based on the size of each ROI of the first ROI group, and the second image setup process comprises transmitting a second scanning pattern to the beam deflector based on the size of each ROI of the second ROI group.

9. A method comprising:
emitting, with an electron source, an electron beam onto a workpiece, wherein the workpiece is disposed on a stage;
receiving, with a detector, electrons formed when the electron beam impacts the workpiece on the stage;
generating, with a processor, a workpiece image based on the electrons received by the detector as the electron beam is scanned across the workpiece;
determining, with the processor, a size and location of each region of interest (ROI) of the workpiece based on the workpiece image;
determining, with the processor, groups of ROIs having similar size based on the size of each ROI of the workpiece, wherein the groups of ROIs comprise at first ROI group and a second ROI group, each comprising a plurality of ROIs;
directing, with a beam deflector, the electron beam onto the location of each ROI of the first ROI group;
generating, with the processor, a first ROI image based on the electrons received by the detector as the electron beam is scanned across each ROI of the first ROI group;
directing, with the beam deflector, the electron beam onto the location of each ROI of the second ROI group; and
generating, with the processor, a second ROI image based on the electrons received by the detector as the electron beam is scanned across each ROI of the second ROI group.

10. The method of claim 9, wherein determining, with the processor, the size and location of each ROI of the workpiece based on the workpiece image comprises:
determining, with the processor, the size and location of each ROI of the workpiece based on a deep learning segmentation algorithm applied to the workpiece image; or
determining, with the processor, the size and location of each ROI of the workpiece based on at least one design image compared to the workpiece image.

11. The method of claim 10, wherein determining, with the processor, the groups of ROIs having similar size based on the size of each ROI of the workpiece comprises:
determining, with the processor, the groups of ROIs having similar size based on the size of each ROI of the workpiece and the deep learning segmentation algorithm; or
determining, with the processor, the groups of ROIs having similar size based on the size of each ROI of the workpiece and the at least one design image.

12. The method of claim 9, wherein directing, with the beam deflector, the electron beam onto the location of each ROI of the first ROI group comprises:
adjusting a voltage applied to an upper sub field deflector and a lower sub field deflector of the beam deflector to direct the electron beam onto the location of each ROI of the first ROI group, while a current applied to an upper main field deflector and a lower main field deflector remains constant.

13. The method of claim 12, wherein directing, with the beam deflector, the electron beam onto the location of each ROI of the second ROI group comprises:
adjusting the voltage applied to the upper sub field deflector and the lower sub field deflector of the beam deflector to direct the electron beam onto the location of each ROI of the second ROI group, while a current applied to the upper main field deflector and the lower main field deflector remains constant.

14. The method of claim 9, wherein the workpiece is divided into a plurality of workpiece sites, and generating, with the processor, the workpiece image based on the electrons received by the detector as the electron beam is scanned across the workpiece comprises:
generating, with the processor, a plurality of workpiece images based on the electrons received by the detector as the electron beam is scanned across each of the plurality of workpiece sites.

15. The method of claim 14, wherein the steps of determining the size and location of each ROI of the workpiece and determining the groups of ROIs having similar size are performed in parallel to the step of generating the plurality of workpiece images.

16. The method of claim 11, before directing, with the beam deflector, the electron beam onto the location of each ROI of the first ROI group, the method further comprises:
performing a first image setup process for the first ROI group.

17. The method of claim 16, wherein performing the first image setup process for the first ROI group comprises transmitting a first scanning pattern to the beam deflector based on the size of each ROI of the first ROI group, and the beam deflector is configured to direct the electron beam onto the location of each ROI of the first ROI group according to the first scanning pattern.

18. The method of claim 16, wherein before directing, with the beam deflector, the electron beam onto the location of each ROI of the second ROI group, the method further comprises: performing a second image setup process the second ROI group.

19. The method of claim 18, wherein performing the second image setup process for the second ROI group comprises transmitting a second scanning pattern to the beam deflector based on the size of each ROI of the second ROI group, and the beam deflector is configured to direct the electron beam onto the location of each ROI of the second ROI group according to the second scanning pattern.
